(19) United States
(12) Patent Application Publication
(10) Pub. No.: US 2026/0319475 A1
(43) Pub. Date: Oct. 15, 2026

(54) PROCESSING APPARATUS, SUBSTRATE PROCESSING APPARATUS, PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Shinichiro MORI, Toyama-shi (JP)

(73) Assignee: Kokusai Electric Corporation, Tokyo (JP)

(21) Appl. No.: 19/638,695

(22) Filed: Apr. 3, 2026

(30) Foreign Application Priority Data
Apr. 10, 2025 (JP) 2025-064743

(51) Int. Cl. G05B 19/418; H10P 72/00

(52) U.S. Cl. CPC G05B 19/4187; G05B 19/4183; H10P 72/0604; G05B 2219/32128; G05B 2219/45031

(57) ABSTRACT

It is possible to display a change in apparatus data in an easy-to-understand manner. There is provided a technique that includes: a display showing a first area and a second area on a screen, wherein a change in a first type of apparatus data containing at least one item is displayed in the first area as a chart in a time series manner, and at least one item is displayed in the second area; a manipulator for selecting an item displayed in the second area and selecting a specified time in the apparatus data displayed in the first area; and a controller for, when the apparatus data for the item selected by the selection by the manipulator is changed during a period including the specified time, controlling the display to switch a display mode used for the period to a display mode different from those of the other periods.

### CROSS-REFERENCE TO RELATED PATENT APPLICATION

This non-provisional U.S. patent application is based on and claims priority under 35 U.S.C. § 119 of Japanese Patent Application No. 2025-064743, filed on Apr. 10, 2025, in the Japanese Patent Office, the entire contents of which are hereby incorporated by reference.

### BACKGROUND

### 1. Field

The present disclosure relates to a processing apparatus, a substrate processing apparatus, a processing method, a method of manufacturing a semiconductor device and a non-transitory computer-readable recording medium.

### 2. Related Art

According to some related arts, apparatus data may be displayed on a screen chronologically in a time series manner.

### SUMMARY

According to the present disclosure, there is provided a technique capable of displaying a change in apparatus data in an easy-to-understand manner.

According to an embodiment of the present disclosure, there is provided a technique that includes: a display configured to be capable of displaying a first area and a second area on a screen, wherein a change in a first type of apparatus data containing at least one item is displayed in the first area as a chart in a time series manner, and information on the at least one item is displayed in the second area; a manipulator configured to be capable of performing a selection operation of selecting an item among the at least one item displayed in the second area and a selection operation of selecting a specified time in the apparatus data displayed in the first area; and a controller configured to be capable of, when the apparatus data for the item selected by the selection operation by the manipulator is changed during a period including the specified time in the apparatus data, controlling the display to switch a display mode used for the period to a display mode different from those of the other periods.

### BRIEF DESCRIPTION OF THE DRAWINGS

FIG. 1 is a diagram schematically illustrating a perspective view of an example of a substrate processing apparatus according to one or more embodiments of the present disclosure.

FIG. 2 is a diagram schematically illustrating a cross-section of the substrate processing apparatus according to the embodiments of the present disclosure when viewed from side.

FIG. 3 is a block diagram schematically illustrating an example of a functional configuration of a control apparatus 100 and its related components of the substrate processing apparatus according to the embodiments of the present disclosure.

FIG. 4 is a diagram schematically illustrating an example of a monitor screen 12 displayed on a display 304.

FIG. 5 is a diagram schematically illustrating another example of the monitor screen 12 displayed on the display 304.

FIG. 6 is a flow chart schematically illustrating an operation of the control apparatus 100 when displaying a period (in which apparatus data for a selected item indicates a change value) in a color different from those of the other periods.

### DETAILED DESCRIPTION

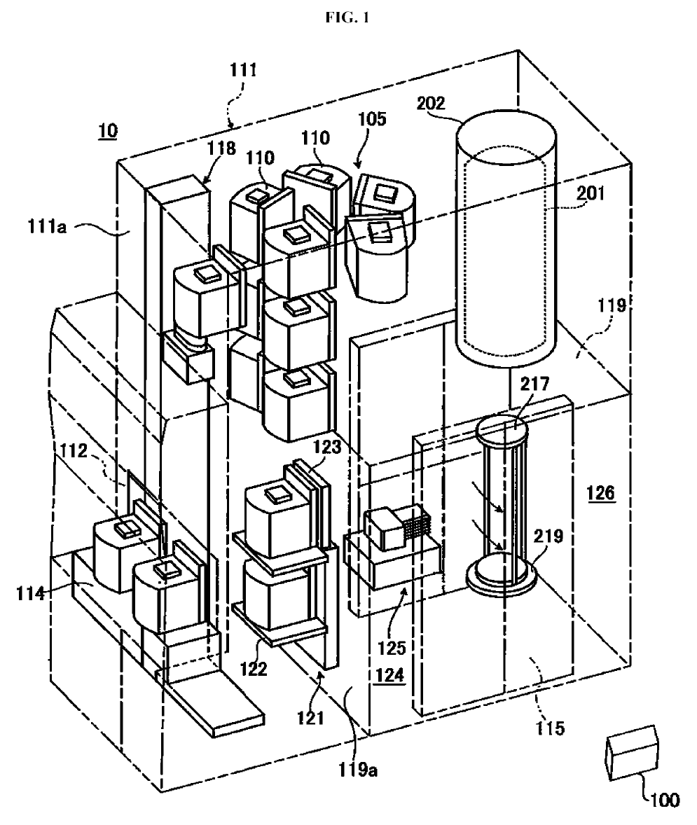

Hereinafter, one or more embodiments (also simply referred to as “embodiments”) according to the technique of the present disclosure will be described mainly with reference to FIGS. 1-6. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, components the same or substantially the same as components described in the drawings are denoted by the same or substantially the same reference numerals, and redundant descriptions related thereto will be omitted. In addition, the technique of the present disclosure is not limited to the embodiments described below. That is, the technique of the present disclosure may be appropriately modified in various ways without departing from the scope thereof.

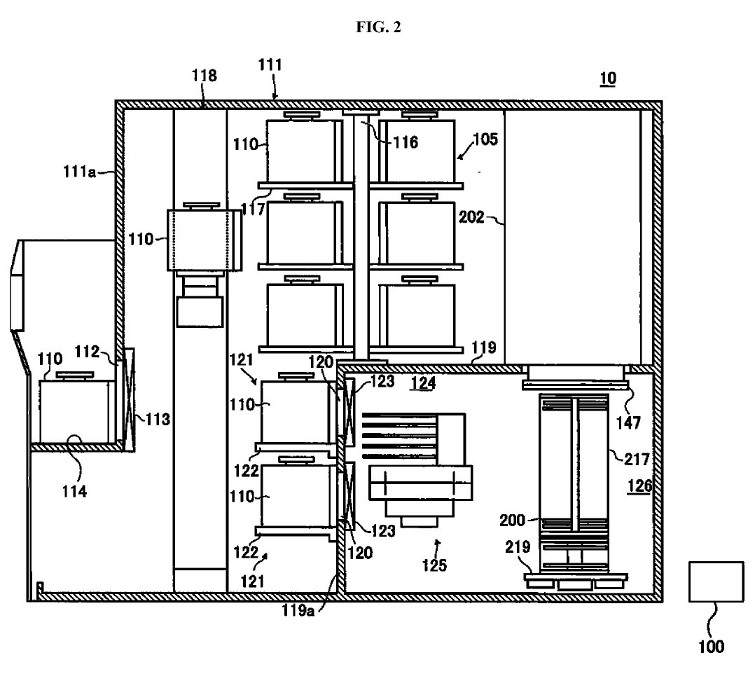

First, with reference to FIGS. 1 and 2, an outline of a substrate processing apparatus 10 according to the present embodiments will be described.

FIG. 1 is a diagram schematically illustrating a perspective view of an example of the substrate processing apparatus 10 according to the present embodiments, and FIG. 2 is a diagram schematically illustrating a cross-section of the substrate processing apparatus 10 according to the present embodiments when viewed from side. In FIGS. 1 and 2, a vertical type substrate processing apparatus is shown as an example of the substrate processing apparatus 10, and a semiconductor wafer made of a material such as silicon is shown as an example of a substrate (that is, a wafer 200 described later) to be processed in the substrate processing apparatus 10. In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, the term “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

As shown in FIGS. 1 and 2, the substrate processing apparatus 10 includes a housing 111. A pod loading/unloading port 112 is provided at a front wall 111a of the housing 111 so as to communicate between an inside (inner portion) and an outside (outer portion) of the housing 111. The pod loading/unloading port 112 can be opened or closed by a front shutter (which is a structure capable of opening and closing the pod loading/unloading port 112) 113. A loading port (which is a loading port shelf, that is, a transfer table for a substrate transfer container) 114 is provided in front of the pod loading/unloading port 112.

For example, a pod 110 is configured as a sealed type substrate transfer container. The pod 110 may be transferred (loaded) into and placed on the loading port 114 by an in-process transfer apparatus (not shown) and may be transferred (unloaded) out of the loading port 114 by the in-process transfer apparatus.

A rotatable pod shelf (which is a storage shelf for the substrate transfer container) 105 is provided in the housing 111 to be located over a substantially center portion of the housing 111 in a front-rear direction. The rotatable pod shelf 105 is configured such that a plurality of pods including the pod 110 can be stored (or placed) on the rotatable pod shelf 105. Hereinafter, the plurality of pods including the pod 110 may also be simply referred to as “pods 110”. The rotatable pod shelf 105 includes a plurality of shelf plates (which are placement shelves for the substrate transfer container) 117 arranged in a multistage manner. Each of the plurality of shelf plates 117 is configured to accommodate at least one among the pods 110.

A pod opener (which is a structure capable of opening and closing a lid of the substrate transfer container) 121 is provided below the rotatable pod shelf 105. The pod opener 121 is provided with a configuration on which the pod 110 is placed and capable of opening and closing a lid of the pod 110.

A pod transfer structure (which is a container transfer structure) 118 is provided among the loading port 114, the rotatable pod shelf 105 and the pod opener 121. The pod transfer structure 118 is configured such that the pod 110 can be transferred among the loading port 114, the rotatable pod shelf 105 and the pod opener 121.

A sub-housing 119 is provided below the substantially center portion of the housing 111 in the front-rear direction to extend toward a rear end of the substrate processing apparatus 10. A pair of wafer loading/unloading ports (substrate loading/unloading ports) 120 through which the wafer 200 serving as the substrate is loaded into or unloaded out of the sub-housing 119 is provided at a front wall 119a of the sub-housing 119.

The pod opener 121 includes: a placement table (which is a mounting table) 122 where the pod 110 is placed thereon; and an opening/closing structure (attaching/detaching structure) 123 capable of opening (or detaching) or closing (or attaching) the lid of the pod 110. The pod opener 121 is configured such that a wafer entrance of the pod 110 is opened or closed by opening or closing the lid of the pod 110 placed on the placement table 122 by the opening/closing structure 123.

The sub-housing 119 defines a transfer chamber 124 fluidically isolated from a space (hereinafter, also referred to as a “pod transfer space”) in which the pod transfer structure 118 or the rotatable pod shelf 105 is provided. A wafer transfer structure (which is a substrate transfer structure) 125 is provided at a front region of the transfer chamber 124. A predetermined number of wafers (for example, as shown in FIG. 2, five wafers) placed on the wafer transfer structure 125 can be moved linearly in a horizontal direction, can be rotated in the horizontal direction and can be elevated or lowered in a vertical direction. The wafer transfer structure 125 is configured such that the wafer 200 can be loaded into or unloaded out of a boat (which is a substrate retainer or a substrate support) 217.

In a rear region of the transfer chamber 124, a standby space 126 where the boat 217 is accommodated in standby is provided, and a process furnace 202 such as a vertical type process furnace is provided above the standby space 126. In addition, the process furnace 202 may also be referred to as a “process vessel” in which the wafer 200 is processed. In the process vessel, the wafer 200 is processed based on a recipe including a plurality of steps defining process conditions for the wafer 200. For example, a process chamber 201 is defined by the process furnace 202.

Subsequently, an operation of the substrate processing apparatus 10 will be described.

When the pod 110 is supplied to the loading port 114, the pod loading/unloading port 112 is opened by the front shutter 113. Then, the pod 110 placed on the loading port 114 is transferred (loaded) into the housing 111 through the pod loading/unloading port 112 by the pod transfer structure 118, and is placed on a designated shelf plate among the plurality of shelf plates 117 of the rotatable pod shelf 105. The pod 110 is temporarily stored at the rotatable pod shelf 105. Then, the pod 110 is transferred from the designated shelf plate among the plurality of shelf plates 117 to the pod opener 121 and is placed on the placement table 122 by the pod transfer structure 118. Alternatively, the pod 110 may be transferred directly from the loading port 114 to the placement table 122.

When an end surface of the pod 110 placed on the placement table 122 is pressed against an opening edge of the wafer loading/unloading port 120 of the front wall 119a of the sub-housing 119, the opening/closing structure 123 detaches the lid of the pod 110 and the wafer entrance of the pod 110 is opened.

When the pod 110 is opened by the pod opener 121, the wafer 200 is then taken out from the pod 110 by the wafer transfer structure 125. Then, by the wafer transfer structure 125, the wafer 200 is transferred (or loaded) into the standby space 126, and loaded (or charged) into the boat 217.

When a predetermined number of wafers including the wafer 200 are charged into the boat 217, a furnace opening of the process furnace 202 closed by a furnace opening shutter 147 is opened by the furnace opening shutter 147. Subsequently, the boat 217 is elevated by a boat elevator 115 such that the boat 217 is loaded (inserted) into the process chamber 201.

After the boat 217 is loaded, the furnace opening is airtightly closed by a seal cap 219. Further, according to the present embodiments, at such a timing (that is, after the boat 217 is loaded), a purge step (also referred to as a “pre-purge step”) of replacing an atmosphere (inner atmosphere) of the process chamber 201 with an inert gas may be performed.

The process chamber 201 is vacuum-exhausted by a vacuum pump (not shown) such that a pressure (inner pressure) of the process chamber 201 reaches and is maintained at a desired pressure (vacuum degree). In addition, the process chamber 201 is heated to a predetermined temperature by a heater (not shown) such that a desired temperature distribution of the process chamber 201 is obtained.

Further, a process gas is supplied from a process gas supply source (not shown). That is, the process gas whose flow rate is controlled to a predetermined flow rate is supplied. The process gas comes into contact with a surface of the wafer 200 while flowing through the process chamber 201. Thereby, a predetermined processing such as a substrate processing described later is performed on the surface of the wafer 200. In addition, the process gas after being subject to a chemical reaction in the predetermined processing is exhausted from the process chamber 201 by a gas exhaust structure (which is a gas exhauster) (not shown). In the present specification, the term “process gas” refers to a gas supplied into the process chamber 201. The same also applies to the following description.

After a predetermined process time has elapsed, the inert gas is supplied from an inert gas supply source (not shown). Thereby, the inner atmosphere of the process chamber 201 is replaced with the inert gas, and the inner pressure of the process chamber 201 is returned to a normal pressure (after-purge step). Then, the boat 217 is lowered by the boat elevator 115 through the seal cap 219. In the present specification, the term “process time” refers to a time duration of continuously performing a process related thereto. The same also applies to the following description.

After the wafer 200 is processed, the wafer 200 and the pod 110 are transferred (unloaded) out of the housing 111 in an order reverse to that of loading the wafer 200 and the pod 110 into the housing 111 described above. Then, another wafer (which is unprocessed) 200 is loaded into the boat 217, and a batch processing for another wafer 200 is performed. For example, the pod 110 accommodating the wafer 200 (which is processed) may be temporarily placed on the rotatable pod shelf 105, then transferred from the designated shelf plate among the plurality of shelf plates 117 to the loading port 114 by the pod transfer structure 118, and then transferred to the outside of the housing 111.

As shown in FIGS. 1 and 2, the substrate processing apparatus 10 includes a control apparatus (which is a control structure) 100, and the control apparatus 100 is configured to control the substrate processing apparatus 10. The control apparatus 100 may be provided (embedded) in the substrate processing apparatus 10, or may be provided outside the substrate processing apparatus 10 in a manner accessible thereto.

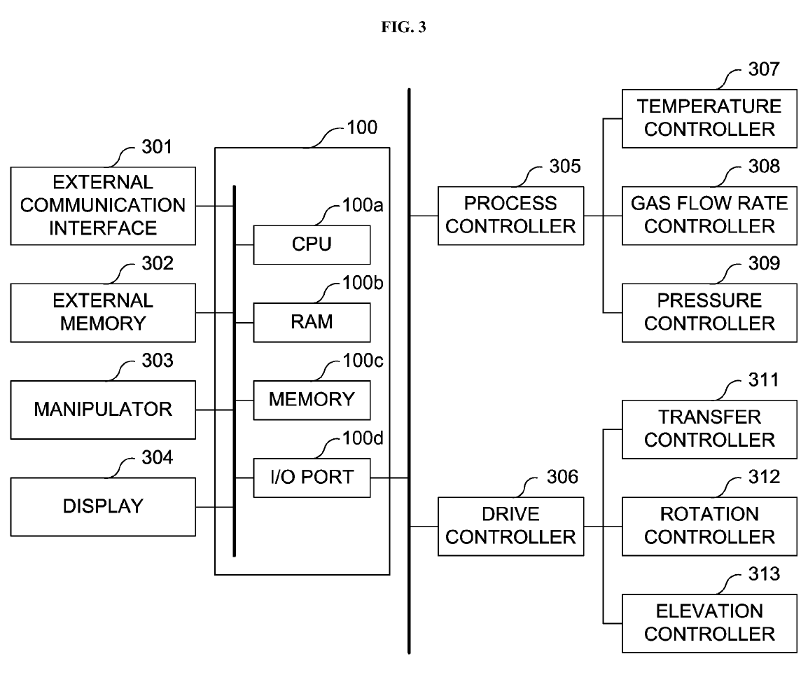

Subsequently, with reference to FIG. 3, a configuration of a control system of the substrate processing apparatus 10 according to the present embodiments will be described. FIG. 3 is a block diagram schematically illustrating an example of a functional configuration of the control apparatus 100 of the substrate processing apparatus 10 according to the present embodiments.

As shown in FIG. 3, the substrate processing apparatus 10 includes the control apparatus (which is a main controller or a primary controller) 100, an external communication interface 301, an external memory 302, a manipulator 303, a display (which is a display structure) 304, a process controller 305 and a drive controller 306.

For example, the control apparatus 100 includes a CPU (Central Processing Unit) 100a serving as a controller, a RAM (Random Access Memory) 100b serving as a volatile memory, a memory 100c and an I/O port (input/output port) 100d. The memory 100c is configured to store apparatus data such as ON/OFF data of the valve acquired by various sensors when the wafer 200 is processed.

The control apparatus 100 is connected to the manipulator 303 and the display 304, and also connected to the process controller 305 and the drive controller 306 via the I/O port 100d. Since the control apparatus 100 is electrically connected to each of the process controller 305 and the drive controller 306 via the I/O port 100d, for example, each piece of data can be transmitted or received and each file can be downloaded or uploaded between the control apparatus 100 and each of the process controller 305 and the drive controller 306.

The control apparatus 100 is connected to an external host computer (not shown) via the external communication interface 301. Therefore, even when the substrate processing apparatus 10 is installed in a clean room, the host computer can be disposed at a location such as an office outside the clean room. In addition, the external memory 302 (which serves as a mounting structure on which a recording medium such as a USB (Universal Serial Bus) memory is installed or removed) is connected to the control apparatus 100.

For example, the manipulator 303 is implemented as a configuration which is integrated with the display 304 as a single structure or which is connected to the display 304 via a connector such as a video cable. For example, the display 304 is configured as a liquid crystal display panel. Various operation screens for operating the substrate processing apparatus 10 can be displayed on the display 304. As one of the operation screens, a monitor screen 12 for the substrate processing is provided. The monitor screen 12 is provided to control a process system controlled by the process controller 305 and a drive system controlled by the drive controller 306. The display 304 is configured to be capable of displaying, on the monitor screen 12, a chart display area (also referred to as a “first area”) 21 where a change in the apparatus data including at least one item is displayed as a chart chronologically in a time series manner and an item selection area (also referred to as a “second area”) 22 where information on the item is displayed. According to the present embodiments, for example, the chart display area 21 is configured such that the apparatus data indicating a change in ON/OFF states of a plurality of valves is displayed as a chart in a time series manner, and the item selection area 22 is configured such that the plurality of valves are displayed as selectable items.

The manipulator 303 is configured to be capable of performing, via the monitor screen 12, a selection operation of selecting one or more valves among the plurality of valves displayed in the item selection area 22 and a selection operation of selecting a specified time in the apparatus data displayed in the chart display area 21. For example, the manipulator 303 is configured to be capable of performing the selection operation of selecting a valve among the plurality of valves and the selection operation of selecting the specified time displayed in the chart display area 21, with respect to the apparatus data indicating the ON/OFF states (open/closed states) of the plurality of valves in a time series manner. In other words, with respect to the apparatus data indicating the ON/OFF states of the plurality of valves in a time series manner, the manipulator 303 is configured to be capable of selecting a specific valve whose ON/OFF state at a selected specified time to be displayed in detail.

When the apparatus data for the valve (specific valve) selected by the selection operation by the manipulator 303 is changed during a period (time duration) including the selected specified time in the apparatus data, the control apparatus 100 is configured to be capable of controlling the display 304 to switch a display mode used for the period to a display mode different from that (or those) of the other periods. Specifically, the control apparatus 100 is configured to be capable of controlling the display 304 to display the period in a color different from those of the other periods. Thereby, it is possible to clearly display the change in the apparatus data, that is, whether the selected valve (that is, the specific valve) is in an ON state or in an OFF state at the specified time.

When the specified time is selected by the selection operation by the manipulator 303, the control apparatus 100 is further configured to be capable of controlling the display 304 such that a straight line extending in the vertical direction is displayed as a time display line 26 at the selected specified time in the chart display area 21. Thereby, it is possible to clearly indicate a position of the selected specified time on the chart display area 21.

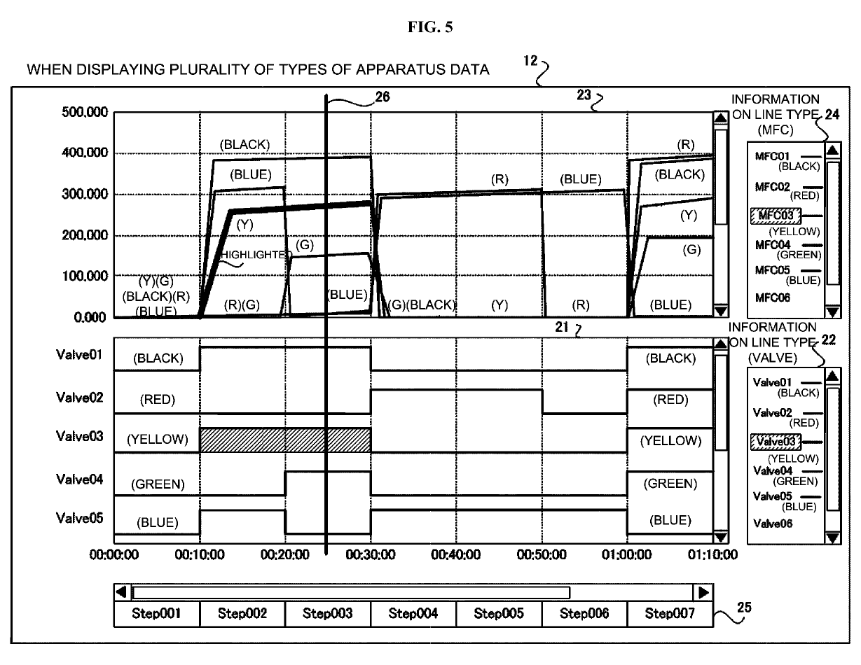

As shown in FIG. 5, the display 304 may also be configured to be capable of displaying, on the monitor screen 12, a chart display area (also referred to as a “third area”) 23 where a change in a second type of the apparatus data including at least one item is displayed as a chart in a time series manner. In addition, the control apparatus 100 may also be configured to be capable of controlling the display 304 to display the chart display area 23 and the chart display area 21 in parallel. According the present embodiments, a display of flow rate data indicating a change in a flow rate in a time series manner in an MFC (mass flow controller) will be described as the second type of the apparatus data. By displaying a plurality of types of the apparatus data related thereto in parallel in a manner described above, it is possible to easily grasp how each type of the apparatus data changes.

The control apparatus 100 is further configured to be capable of controlling the display 304 to display the chart display area 21 and the chart display area 23 in parallel such that a time indicated in the chart display area 21 and a time indicated in the chart display area 23 are synchronized. By displaying a plurality of types of the apparatus data related thereto in parallel in a synchronized manner described above, it is possible to easily grasp a relationship between changes in each type of the apparatus data.

The control apparatus 100 is further configured to be capable of controlling the display 304 to switch the display mode used for the period in the chart display area 23 including the selected specified time in the apparatus data for the MFC related to the valve selected by the selection operation by the manipulator 303 to the display mode different from that (or those) of the other periods. In addition, the control apparatus 100 is further configured to be capable of controlling the display 304 to switch a line type or a display color used for the period including the selected specified time in the apparatus data for the MFC related to the valve selected by the selection operation by the manipulator 303 to a line type or a display color different from a line type or a display color of the other periods in the chart display area 23. Thereby, it is possible to easily grasp, in the chart display area 23, data related to the apparatus data whose display mode has been switched in the chart display area 21.

The control apparatus 100 is further configured to be capable of controlling the display 304 to display the change in the apparatus data as a chart by differentiating the display color for each item (such as the valve and the MFC). By switching the display color for each item in a manner described above, it is possible to distinguish and check a plurality of items displayed in the same area.

The control apparatus 100 is further configured to be capable of controlling the display 304 to display the change in the apparatus data as a rectangular chart in the chart display area 21. By displaying the ON/OFF state (open/closed state) of the valve as the rectangular chart in a manner described above, it is possible to easily determine whether the valve is in the ON state or in the OFF state.

The control apparatus 100 is further configured to be capable of controlling the display 304 to display the change in the apparatus data for a plurality of valves by arranging them in the vertical direction in parallel in the chart display area 21, and to display the plurality of valves by using pre-set line types by arranging them in parallel in the item selection area 22. Thereby, it is possible to easily grasp the change in the apparatus data for a plurality of items of the same type.

In addition, a reference value and a change value set for each valve are shown in the chart for the apparatus data displayed in the chart display area 21. Specifically, the reference value is a value indicating that the valve is in the OFF state (closed state), and the change value is a value indicating that the valve is in the ON state (open state). The control apparatus 100 is further configured to be capable of controlling the display 304 to display a difference area (which ranges between the reference value and the change value for the period including the specified time) in a color different from those of the other areas. Thereby, it is possible to easily grasp a range of change in the apparatus data.

When a value of the apparatus data for the valve is the change value (that is, in the ON state) in the period including the selected specified time in the apparatus data for the valve selected by the selection operation by the manipulator 303, the control apparatus 100 is further configured to be capable of controlling the display 304 to display a period (from a start time at which the apparatus data is changed from the OFF state to the ON state before the selected specified time to an end time at which the apparatus data is changed from the ON state to the OFF state after the selected specified time) in a color different from those of the other periods. Thereby, it is possible to clearly grasp a period in which the apparatus data is changed from the OFF state to the ON state.

The display 304 is further configured to be capable of displaying, on the monitor screen 12, an item selection area (also referred to as a “fourth area”) 24 where the MFC to be displayed in the chart display area 23 is selected. In addition, the control apparatus 100 is further configured to be capable of controlling the display 304 to display the apparatus data for the MFC selected in the item selection area 24 in the chart display area 23 without displaying the apparatus data for the other MFCs. Thereby, it is possible to make a chart display of the MFC (which is selected in the item selection area 24) easier to see.

When a plurality of MFCs are selected in the item selection area 24, the control apparatus 100 is further configured to be capable of controlling the display 304 such that, in the chart display area 23, the apparatus data for the plurality of MFCs selected in the item selection area 24 is displayed overlappingly in a time series manner. For the apparatus data in the same unit, such as flow rates of the MFCs, it is easier to see the change in a value of each MFC when displayed as overlapped in a time series manner rather than displayed in parallel. Thereby, it is possible to easily grasp the change in the flow rates of the plurality of MFCs.

The control apparatus 100 may also be configured to be capable of controlling the display 304 such that, in the chart display area 23, the display mode used for the period including the selected specified time in the apparatus data for the MFC related to the valve selected by the selection operation by the manipulator 303 is switched to the display mode different from that (or those) of the other periods, and such that a display mode of the MFC related to the valve selected in the item selection area 24 is also switched to a display mode different from that (or those) of the other MFCs. Thereby, it is possible to easily grasp (or identify) the MFC displayed in a different display mode from the others in the item selection area 24.

The display 304 is further configured to be capable of displaying a recipe step information display area (also referred to as a “fifth area”) 25 below the chart display area 21 on the monitor screen 12. In the recipe step information display area 25, information on the plurality of steps constituting the recipe is displayed in a synchronized time series manner. The control apparatus 100 is further configured to be capable of controlling the display 304 such that the apparatus data and step information of the recipe are displayed slidably in accordance with an operation of a scroll bar located below the chart display area 21. By displaying the chart in a time series manner and the step information of the recipe together on the monitor screen 12 in a manner described above, it is possible to easily grasp (or identify) which step corresponds to the specified time being displayed.

For example, the manipulator 303 outputs the information displayed on the display 304 to a component (device) such as the USB memory inserted in the external memory 302. The manipulator 303 accepts (or receives) input data (input instruction) from the operation screen displayed on the display 304 and transmits the input data to the control apparatus 100. Further, the manipulator 303 is configured to receive an instruction (control instruction) to execute an appropriate substrate processing recipe (also referred to as a “process recipe”) among recipes loaded (or deployed) in the RAM 100b or recipes stored in the memory 100c, and is further configured to transmit the instruction to the control apparatus 100. For example, the manipulator 303 and the display 304 may be configured as a touch panel. According to the present embodiments, the manipulator 303 and the display 304 are provided separately from the control apparatus 100. However, the manipulator 303, the display 304 and the control apparatus 100 may be integrated into a single structure.

The process controller 305 includes controllers (sub-controllers) such as a temperature controller 307, a gas flow rate controller 308 and a pressure controller 309. That is, each of the temperature controller 307, the gas flow rate controller 308 and the pressure controller 309 may also be referred to as the “sub-controller”, and is electrically connected to the process controller 305. Thereby, for example, each piece of data can be transmitted or received and each file can be downloaded or uploaded between the process controller 305 and each sub-controller. In addition, while the process controller 305 and each sub-controller (that is, the temperature controller 307, the gas flow rate controller 308 and the pressure controller 309) are illustrated separately, the process controller 305 and each sub-controller may be integrated into a single structure.

The temperature controller 307 is configured to control a process temperature based on setting values for a plurality of zones defined (or set) in the recipe and measured values detected by a plurality of temperature sensors (not shown) respectively installed in the plurality of zones. Specifically, the temperature controller 307 is configured to adjust a temperature (inner temperature) of the process chamber 201 or a temperature of the wafer 200 by controlling temperatures of heaters (not shown) respectively provided corresponding to the zones. In the present specification, the term “process temperature” refers to the “temperature of the wafer 200” or the “inner temperature of the process chamber 201”.

Each zone refers to an area (or a region) obtained by dividing the process chamber 201 into a plurality of areas (regions) in a height direction. According to the present embodiments, for example, the process chamber 201 is divided into five areas. In addition, the number of the zones is not limited to five, and the process chamber 201 may be divided into zones other than five zones depending on a configuration of an apparatus (that is, the substrate processing apparatus 10). In addition, the heaters may be provided corresponding to the zones, respectively. According to the present embodiments, for example, five heaters are provided corresponding to the five zones. The temperature of the wafer 200 or the inner temperature of the process chamber 201 is controlled by the five heaters.

The gas flow rate controller 308 is configured to adjust a flow rate of the gas (which is supplied into the process chamber 201) to a desired flow rate based on the setting value defined (or set) in the recipe and measured values detected by a gas flow rate sensor (not shown). Specifically, the gas flow rate controller 308 is configured to control an opening and closing operation of a valve in accordance with an opening/closing state of the valve defined (or set) in the recipe. The gas flow rate controller 308 is configured to adjust the flow rate of the gas supplied into the process chamber 201 by controlling the opening and closing operation of the valve and an operation of a mass flow controller (MFC) serving as a flow rate controller (flow rate control structure).

The pressure controller 309 is configured to control a process pressure based on the setting value defined (or set) in the recipe and pressure values detected by a pressure sensor (not shown). Specifically, the pressure controller 309 is configured to control a switching operation (on/off operation) of a pressure regulator (which is a pressure adjusting structure) and a switching operation of the vacuum pump (not shown) such that the inner pressure of the process chamber 201 reaches and is maintained at a desired pressure at a desired timing. In the present specification, the term “process pressure” refers to the inner pressure of the process chamber 201.

The drive controller 306 includes controllers (sub-controllers) such as a transfer controller 311, a rotation controller 312 and an elevation controller 313. In addition, while the drive controller 306 and each sub-controller (that is, the transfer controller 311, the rotation controller 312 and the elevation controller 313) are illustrated separately, the drive controller 306 and each sub-controller may be integrated into a single structure.

For example, the transfer controller 311 is configured to control each transfer operation of components such as the boat elevator 115, the pod transfer structure 118 and the wafer transfer structure 125.

For example, the rotation controller 312 is configured to control each rotation operation of components such as the pod transfer structure 118, the wafer transfer structure 125 and a rotating shaft 116 located at a center of the rotatable pod shelf 105.

For example, the elevation controller 313 is configured to control each elevation operation (elevating and lowering operation) of components such as the boat elevator 115, the pod transfer structure 118 and the wafer transfer structure 125.

In addition, according to the present embodiments, each of the control apparatus 100, the process controller 305 and the drive controller 306 may be embodied by a general computer system without being limited to a dedicated computer system. For example, by installing, in the general computer system, a program for executing the predetermined processing described above from a predetermined recording medium such as a CD-ROM and a USB memory storing the program, each controller described above may be provided to perform the predetermined processing.

In addition, a method of supplying the program described above can be appropriately selected. Instead of or in addition to being supplied through the predetermined recording medium as described above, for example, the program may be provided through a communication interface such as a communication line, a communication network and a communication system.

Further, the control apparatus 100 is configured as a computer including the CPU 100a, the RAM 100b, the memory 100c and the I/O port 100d. In the memory 100c, for example, a recipe file such as a recipe in which process procedures and the process conditions for the substrate processing are defined, a control program file for executing the recipe file, a parameter file (setting value file) in which parameters for setting the process procedures and the process conditions are defined, an error processing program file, a parameter file for an error processing, various screen files including an input screen to be used to input process parameters and various icon files and the like (which are not shown) are stored (or saved). In the memory 100c, for example, the apparatus data for each item acquired while the wafer 200 is being processed and a control program file for displaying the change in the apparatus data for each item on the display 304 are also stored (or saved). For example, the control apparatus 100 is electrically connected to a network such as the Internet, a LAN (Local Area Network) and a WAN (Wide Area Network) by using the external communication interface 301, and is configured to be capable of communicating with external apparatuses via the network.

As the memory 100c, for example, a non-volatile memory such as a hard disk drive (HDD), a solid state drive (SSD) and a flash memory may be used.

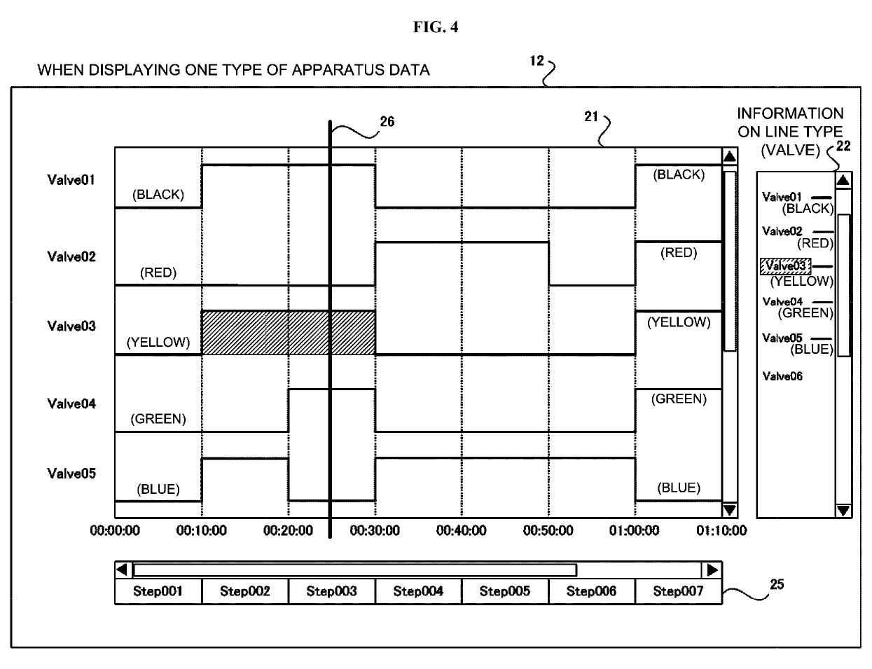

FIG. 4 is a diagram schematically illustrating an example of the monitor screen 12 displayed on the display 304. On the monitor screen 12 shown in FIG. 4, one type of the apparatus data (that is, the ON/OFF data of the valves) is displayed as a chart.

On the monitor screen 12 shown in FIG. 4, the chart display area 21, the item selection area 22 and the recipe step information display area 25 are displayed. In the chart display area 21, the apparatus data indicating chronological changes in the ON/OFF states of five valves (“Valve01” to “Valve05”) is displayed as a chart. In addition, in the item selection area 22, each of the five valves is displayed as a selectable item, and in the chart display area 21, the specified time is displayed as the time display line 26. In addition, below the chart display area 21, the recipe step information display area 25 is displayed. In the recipe step information display area 25, information on the plurality of steps constituting the recipe is displayed in a time series manner.

In FIG. 4, shown is an example in which an item “Valve03” is selected in the item selection area 22 by a user operation and a specified time “00:25:00” (that is, 25 minutes after a start of the processing of the wafer 200) is selected by a user operation. At such a specified time, the valve named “Valve03” is in the ON state. Therefore, the control apparatus 100 is configured to display a period (from a time “00:10:00” at which the valve is changed from the OFF state to the ON state to a time “00:30:00” at which the valve is changed from the ON state to the OFF state) in a color different from those of the other periods.

By viewing the monitor screen 12 in such a state, a user can easily grasp a period (between a time before and a time after the specified time “00:25:00”) during which the selected valve “Valve03” is in the ON state.

FIG. 5 is a diagram schematically illustrating another example of the monitor screen 12 displayed on the display 304. On the monitor screen 12 shown in FIG. 5, two different types of the apparatus data (that is, the ON/OFF data of the valves and the flow rate data of the MFCs) are displayed as a chart.

In addition to the chart display area 21, the item selection area 22 and the recipe step information display area 25, the chart display area 23 and the item selection area 24 are also displayed in the monitor screen 12 shown in FIG. 5.

The present embodiments will be described by way of an example in which the five valves (“Valve01” to “Valve05”) and five MFCs (“MFC01” to “MFC05”) are related to each other.

On the monitor screen 12 shown in FIG. 5, the chart display area 21 (where the apparatus data for the ON/OFF state of the valve is displayed in a time series manner) and the chart display area 23 (where the flow rate of the MFC is displayed in a time series manner) are displayed in parallel and synchronized. Therefore, by viewing the monitor screen 12 in such a state, the user can easily grasp the relationship between changes in each type (or each piece) of the apparatus data. In other words, by comparing the chart display areas 21 and 23, the user can determine which MFC's flow rate is increased when the valve is turned on (that is, the valve is switched to the ON state) and which MFC's flow rate is decreased when the valve is turned off (that is, the valve is switched to the OFF state).

Then, when the user selects the valve “Valve03” in the item selection area 22 and the specified time, a period (which includes the specified time) in the apparatus data for the valve “Valve03” is displayed in the chart display area 21 in a color different from those of the other periods. In addition, in the chart display area 23, a period corresponding to the flow rate data for the MFC “MFC03” related to the valve “Valve03” is highlighted with a thick line. In addition, in the item selection area 24, the item “MFC03” is displayed in a display mode different from that (or those) of the other items.

Thereby, the user can grasp the period in the flow rate data for the MFC “MFC03” corresponding to the valve “Valve03” which is in the ON state at the specified time.

In addition, in the chart display area 23, the flow rate data from the plurality of MFCs are displayed in an overlapping manner. However, the flow rate data from the plurality of MFCs are displayed in different colors such as red, black, yellow, green and blue, for example. In addition, in the item selection area 24, the correspondence between the colors and the MFCs (that is, which color corresponds to which MFC) is displayed. Therefore, the user can easily grasp which flow rate data belongs to which MFC. In addition, while the display color of the apparatus data in FIGS. 4 and 5 is indicated by text such as “(RED)” or “(R)”, each piece of the apparatus data is displayed in a different color on the actual monitor screen 12. In FIGS. 4 and 5, black is indicated by “(BLACK)”, red is indicated by “(RED)” or “(R)”, yellow is indicated by “(YELLOW)” or “(Y)”, green is indicated by “(GREEN)” or “(G)”, and blue is indicated by “(BLUE)”.

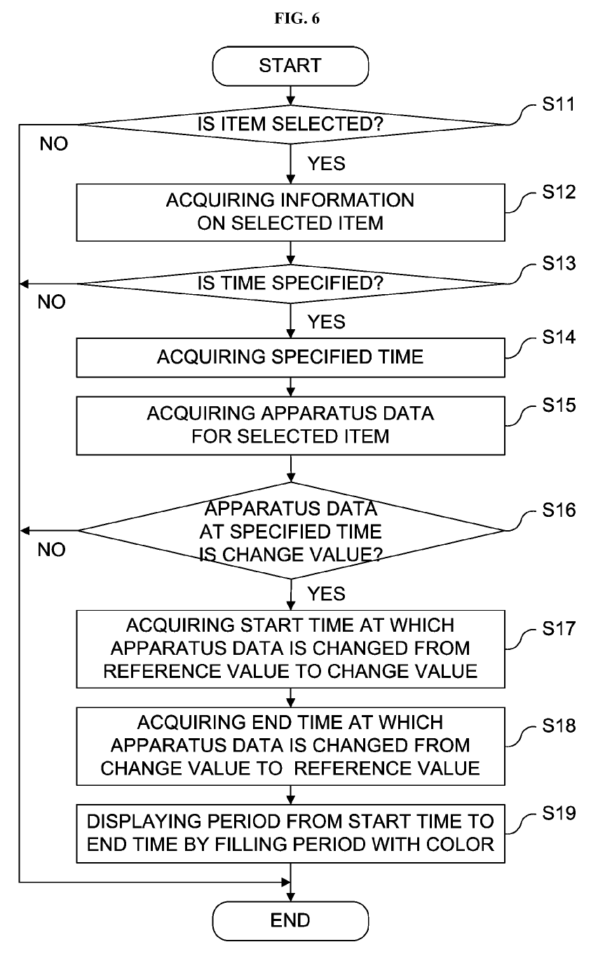

Subsequently, a processing (operation) of the control apparatus 100 according to the present embodiments when displaying the period (where the apparatus data for the selected item is the change value) in a color different from those of the other periods will be described with reference to a flow chart shown in FIG. 6. For example, the operation caused by the user operation on the monitor screen 12 shown in FIG. 4 will be described.

First, in a step S11, the control apparatus 100 determines whether an item is selected in the item selection area 22 on the monitor screen 12 of FIG. 4. Specifically, the control apparatus 100 determines whether one of the five valves (“Valve01” to “Valve05”) is selected. When no valve is selected in the step S11, the control apparatus 100 terminates the processing.

When the item (that is, one of the five valves) is selected in the step S11, the control apparatus 100 acquires information on the selected item in a step S12. In FIG. 4, since the item “Valve03” is selected in the item selection area 22, the control apparatus 100 acquires the information on “Valve03” as the information on the selected item.

Subsequently, in a step S13, the control apparatus 100 determines whether a time is specified on the monitor screen 12 of FIG. 4. When it is determined in the step S13 that the time is not specified, the control apparatus 100 terminates the processing.

When it is determined in the step S13 that the time is specified, the control apparatus 100 acquires information on the specified time in a step S14. Then, in a step S15, the control apparatus 100 acquires the apparatus data for the selected item, that is, the selected valve “Valve03”.

Subsequently, in a step S16, the control apparatus 100 determines whether the apparatus data at the specified time is the change value, that is, whether it is in the ON state. When it is determined in the step S16 that the apparatus data at the specified time is the reference value, that is, it is in the OFF state, the control apparatus 100 terminates the processing.

On the contrary, when it is determined in the step S16 that the apparatus data at the specified time is the change value, that is, it is in the ON state, the control apparatus 100 acquires, as the start time, the time at which the apparatus data is changed from the reference value to the change value, that is, from the OFF state to the ON state, in a step S17.

Subsequently, in a step S18, the control apparatus 100 acquires, as the end time, the time at which the apparatus data is changed from the change value to the reference value, that is, from the ON state to the OFF state.

Finally, in a step S19, the control apparatus 100 instructs the display 304 to display the period from the start time to the end time in the apparatus data for the valve “Valve03” in a color different from those of the other periods. In accordance with an instruction from the control apparatus 100, the display 304 displays the period from the start time to the end time in the apparatus data for the valve “Valve03” in the chart display area 21 in the color different from those of the other periods.

As a result of such a processing, it can be seen that the period from the time “00:10:00” to the time “00:30:00” in the apparatus data for the valve “Valve03” is displayed in the color different from those of the other periods on the monitor screen 12 shown in FIG. 4. Therefore, the user can clearly grasp the period during which the apparatus data is in the ON state, and can easily grasp the change in the apparatus data.

For example, the embodiments mentioned above are described by way of an example in which the substrate processing apparatus 10 is used. However, the technique of the present disclosure may also be applied to a program that causes a computer to perform the functions of the substrate processing apparatus 10. Further, the technique of the present disclosure may also be applied to a non-transitory computer-readable recording medium storing the program that causes the computer to perform the functions of the substrate processing apparatus 10.

For example, the configuration of the substrate processing apparatus 10 described in the embodiments mentioned above is merely an example, and may be changed in accordance with circumstances without departing from the scope of the technique of the present disclosure.

For example, the process flow of the program described in the embodiments mentioned above is merely an example, and may be changed. For example, an unnecessary step may be deleted, a new step may be added, or the process procedures may be changed without departing from the scope of the technique of the present disclosure.

For example, the embodiments mentioned above are described by way of an example in which the processing according to the embodiments is implemented by a software configuration that uses the computer to execute the program. However, the technique of the present disclosure is not limited thereto. For example, the technique of the present disclosure may also be applied to a hardware configuration capable of performing the processing, or may also be applied to a combination of hardware and software configurations capable of performing the processing.

For example, the embodiments mentioned above are described by way of an example in which a batch type substrate processing apparatus capable of simultaneously processing a plurality of substrates is used to form a film. However, the technique of the present disclosure is not limited thereto. For example, the technique of the present disclosure may also be preferably applied when a single wafer type substrate processing apparatus capable of processing one or several substrates at a time is used to form the film. In addition, the embodiments mentioned above are described by way of an example in which a substrate processing apparatus including a hot wall type process furnace is used to form the film. However, the technique of the present disclosure is not limited thereto. For example, the technique of the present disclosure may also be preferably applied when a substrate processing apparatus including a cold wall type process furnace is used to form the film.

The process procedures and the process conditions for each process using the substrate processing apparatuses exemplified above may be substantially the same as those of the embodiments mentioned above. Even in such a case, it is possible to obtain substantially the same effects as in the embodiments mentioned above.

As described above, according to some embodiments of the present disclosure, it is possible to display the change in the apparatus data in an easy-to-understand manner.

What is claimed is:

1. A processing apparatus comprising:
a display configured to be capable of displaying a first area and a second area on a screen, wherein a change in a first type of apparatus data containing at least one item is displayed in the first area as a chart in a time series manner, and information on the at least one item is displayed in the second area;
a manipulator configured to be capable of performing a selection operation of selecting an item among the at least one item displayed in the second area and a selection operation of selecting a specified time in the apparatus data displayed in the first area; and
a controller configured to be capable of, when the apparatus data for the item selected by the selection operation by the manipulator is changed during a period comprising the specified time in the apparatus data, controlling the display to switch a display mode used for the period to a display mode different from those of the other periods.

2. The processing apparatus of claim 1, wherein the controller is further configured to be capable of controlling the display to display the period in a color different from those of the other periods.

3. The processing apparatus of claim 1, wherein the controller is further configured to be capable of, when the specified time is selected by the selection operation by the manipulator, controlling the display such that a straight line extending in a vertical direction is displayed in the first area at the specified time selected by the selection operation.

4. The processing apparatus of claim 1, wherein the display is further configured to be capable of displaying a third area on the screen, wherein a change in a second type of the apparatus data containing at least one item is displayed in the third area as a chart in a time series manner, and
wherein the controller is further configured to be capable of controlling the display to display the first area and the third area in parallel.

5. The processing apparatus of claim 4, wherein the controller is further configured to be capable of controlling the display to display the first area and the third area in parallel such that a time indicated in the first area and a time indicated in the third area are synchronized.

6. The processing apparatus of claim 4, wherein the controller is further configured to be capable of controlling the display, in the third area, to switch a display mode used for the period comprising the specified time in the second type of the apparatus data for an item related to the item in the first type of the apparatus data selected by the selection operation by the manipulator to a display mode different from those of the other periods.

7. The processing apparatus of claim 6, wherein the controller is further configured to be capable of controlling the display, in the third area, to switch a line type or a display color used for the period comprising the specified time in the second type of the apparatus data for the item related to the item in the first type of the apparatus data selected by the selection operation by the manipulator to a line type or a display color different from those of the other periods.

8. The processing apparatus of claim 1, wherein the controller is further configured to be capable of controlling the display to display the change in the apparatus data as a chart by differentiating a display color for each item.

9. The processing apparatus of claim 1, wherein the controller is further configured to be capable of controlling the display to display the change in the apparatus data as a rectangular chart in the first area.

10. The processing apparatus of claim 1, wherein the controller is further configured to be capable of controlling the display to display the change in the apparatus data for a plurality of items in a vertical direction in parallel in the first area, and to display the plurality of items by using pre-set line types in parallel in the second area.

11. The processing apparatus of claim 1, wherein a reference value and a change value are set for each item in the chart, and
wherein the controller is further configured to be capable of controlling the display to display a difference area in a color different from those of the other areas, wherein the difference area ranges between the reference value and the change value for the period.

12. The processing apparatus of claim 11, wherein the controller is further configured to be capable of, when the change value in the period comprising the specified time in the apparatus data is selected by the selection operation by the manipulator as a value of the apparatus data for the item, controlling the display to display, in a color different from those of the other periods, a period from a start time at which the apparatus data is changed from the reference value to the change value before the specified time to an end time at which the apparatus data is changed from the change value to the reference value after the specified time.

13. The processing apparatus of claim 4, wherein the display is further configured to be capable of displaying a fourth area on the screen, wherein an item to be displayed in the third area is selected in the fourth area, and
wherein the controller is further configured to be capable of controlling the display to display, in the third area, apparatus data for the item selected in the fourth area without displaying apparatus data for the other items in the third area.

14. The processing apparatus of claim 13, wherein the controller is further configured to be capable of, when a plurality of items are selected in the fourth area, controlling the display such that apparatus data for the plurality of items selected in the fourth area is displayed overlappingly in the third area in a time series manner.

15. The processing apparatus of claim 13, wherein the controller is further configured to be capable of controlling the display, in the third area, to switch a display mode used for the period comprising the specified time in the second type of the apparatus data for an item related to the item in the first type of the apparatus data selected by the selection operation by the manipulator to a display mode different from those of the other periods, and to switch a display mode of an item in the second type of the apparatus data selected in the fourth area and related to the item in the first type of the apparatus data to a display mode different from those of the other items.

16. A substrate processing apparatus comprising:
the processing apparatus of claim 1.

17. The substrate processing apparatus of claim 16, wherein the display is further configured to be capable of displaying a fifth area below the first area on the screen, wherein information on a plurality of steps constituting a recipe is displayed in a synchronized time series manner, and
wherein the controller is further configured to be capable of controlling the display such that the apparatus data and the information on the plurality of steps is displayed slidably in accordance with an operation of a scroll bar located below the first area.

18. A processing method comprising:
(a) displaying a first area and a second area on a screen, wherein a change in a first type of apparatus data containing at least one item is displayed in the first area as a chart in a time series manner, and information on the at least one item is displayed in the second area;
(b) performing a selection operation of selecting an item among the at least one item displayed in the second area;
(c) performing a selection operation of selecting a specified time in the apparatus data displayed in the first area; and
(d) when the apparatus data for the item selected by the selection operation in (b) is changed during a period comprising the specified time in the apparatus data selected by the selection operation in (c), switching a display mode used for the period to a display mode different from those of the other periods.

19. A method of manufacturing a semiconductor device, comprising
the method of claim 18.

20. A non-transitory computer-readable recording medium storing a program that causes a substrate processing apparatus, by a computer, to perform:
(a) displaying a first area and a second area on a screen, wherein a change in a first type of apparatus data containing at least one item is displayed in the first area as a chart in a time series manner, and information on the at least one item is displayed in the second area;
(b) performing a selection operation of selecting an item among the at least one item displayed in the second area;
(c) performing a selection operation of selecting a specified time in the apparatus data displayed in the first area; and
(d) when the apparatus data for the item selected by the selection operation in (b) is changed during a period comprising the specified time in the apparatus data selected by the selection operation in (c), switching a display mode used for the period to a display mode different from those of the other periods.
